(19) United States
(12) Patent Application Publication
(10) Pub. No.: US 2003/0219053 A1
(43) Pub. Date: Nov. 27, 2003

(54) Index guided laser structure

(75) Inventors: Reuel B. Swint, Savoy, IL (US); James J. Coleman, Monticello, IL (US); Mark Zediker, St. Charles, MO (US)

Correspondence Address: GREER, BURNS & CRAIN, 300 S WACKER DR, 25TH FLOOR, CHICAGO, IL, 60606, US

(73) Assignee: The Board of Trustees of the University of Illinois

(21) Appl. No.: 10/369,319

(22) Filed: Feb. 19, 2003

Related U.S. Application Data
(60) Provisional application No. 60/382,355, filed on May 21, 2002.

(51) Int. Cl. H01S 5/00; H01S 3/03

(52) U.S. Cl. 372/46

(57) ABSTRACT

An index guide laser structure of the invention utilizes the combination of two spatial filter elements to limit or eliminate oscillation of high order lateral modes and beam steering. A preferred structure utilizes a frustrated and curved index guide to induce bend loss in higher order modes, and another preferred structure utilizes frustrating guides to introduce periodic interruptions of the refractive index outside the central guide to induce scattering loss in the higher order modes.

### RELATED APPLICATIONS AND PRIORITY CLAIM

The present Application claims priority under Title 35 U.S.C. §119 on copending U.S. Provisional Application No. 60/382,355, filed May 21, 2002.

### TECHNICAL FIELD

The field of the invention is index guided lasers.

### BACKGROUND ART

Index guided lasers are used in many applications, such as telecommunications, optical disk storage, spectroscopy, medical therapy, and materials processing. Conventionally designed laser diodes will operate on a single lateral mode at low output powers. But at high output powers, additional high order lateral modes begin to lase, which diminishes the brightness of the laser.

A prior method for maintaining a single lateral mode operation consists of designing laser waveguides that are narrow in width and have a small index step. In theory, the narrow, small index step waveguide does not support propagation of higher order modes. In practice, the presence of gain, spatial hole burning and thermal lensing alter the refractive index profile to support propagation of higher order modes. Although this technique is an effective and highly preferred method at medium and low power levels, it is not usually effective at suppressing the onset of high order modes at very high output powers, e.g., ˜0.5W and higher. Also, the small size of the narrow device ultimately limits the total output power that can be obtained from the diode. The challenge is to limit or eliminate higher order lateral modes, which cause beam instability, a large diffraction angle, and poor fiber coupling efficiency.

### DISCLOSURE OF INVENTION

An index guide laser structure of the invention utilizes the combination of two spatial filter elements to limit or eliminate oscillation of high order lateral modes and beam steering. A preferred structure utilizes a frustrated and curved index guide to induce bend loss in higher order modes, and another preferred structure utilizes frustrating guides to introduce periodic interruptions of the refractive index outside the central guide to induce scattering loss in the higher order modes.

### BRIEF DESCRIPTION OF THE DRAWINGS

Other features, objects and advantages of the invention will be apparent to artisans from the detailed description and drawings, of which:

FIG. 1 is a schematic perspective view of a preferred embodiment buried ridge waveguide laser in accordance with the invention;

FIG. 2 is a schematic top view of the curved and frustrated index guide shown in FIG. 1;

FIG. 3 is a schematic top view of a preferred embodiment index guide of the invention;

FIG. 4 is an explanatory operational schematic of the frustrating scattering index guides shown in FIG. 3;

FIG. 5 is a schematic cross-sectional view to illustrate a preferred formation process for a preferred embodiment buried ridge guide laser in accordance with FIG. 1;

FIG. 6 is a schematic top view of a preferred embodiment frustrated and curved index guide of the invention with frustrating scattering scattering centers;

FIG. 7 is a schematic top view of an alternate preferred embodiment frustrated index guide of the invention;

FIG. 8 is a schematic perspective view of a preferred embodiment ridge waveguide laser of the invention; and

FIG. 9 is a schematic perspective view of a preferred embodiment self-aligned laser of the invention.

### BEST MODE OF CARRYING OUT THE INVENTION

An index guide laser structure of the invention utilizes an index guide having a combination of two spatial filter elements to prevent oscillation of high order lateral modes and beam steering. A preferred index guide structure utilizes a spatial filter formed from a frustrated and curved index guide structure. The guide structure uses a central index guide having a curve to induce bend loss in higher order modes. The central index guide is coupled to a pair of frustrating guides to introduce additional lateral radiation loss in higher order modes. Another preferred index guide structure utilizes periodic interruptions of the refractive index outside the central guide to induce scattering loss in the higher order modes. Index guide structures of the invention are completely compatible with conventional laser diode processing and add no complexity or additional fabrication steps to the production of the laser. The invention is applicable to all index guided lasers, e.g., buried ridge lasers, ridge waveguide lasers and self aligned waveguide lasers.

The invention will now be illustrated by discussing some preferred embodiment laser devices and illustrating exemplary index guides. Many of the index guides are illustrated as ridges. However, other types of guides are also contemplated. For example, induced disordering, lateral oxidation, and surface plasmons may establish a waveguide. Embodiments of the invention include use of inventive principles with guides other than ridges. In describing the invention, particular exemplary devices, formation processes, and device applications will be used for purposes of illustration. Dimensions and illustrated devices may be exaggerated for purposes of illustration and understanding of the invention. The elements of the drawings are not necessarily to scale relative to each other. Like reference numerals designate corresponding similar though not necessarily exact parts through the several views. Schematic views will be understood by artisans as such views are commonly used in the art. Devices of the invention may be formed using conventional equipment.

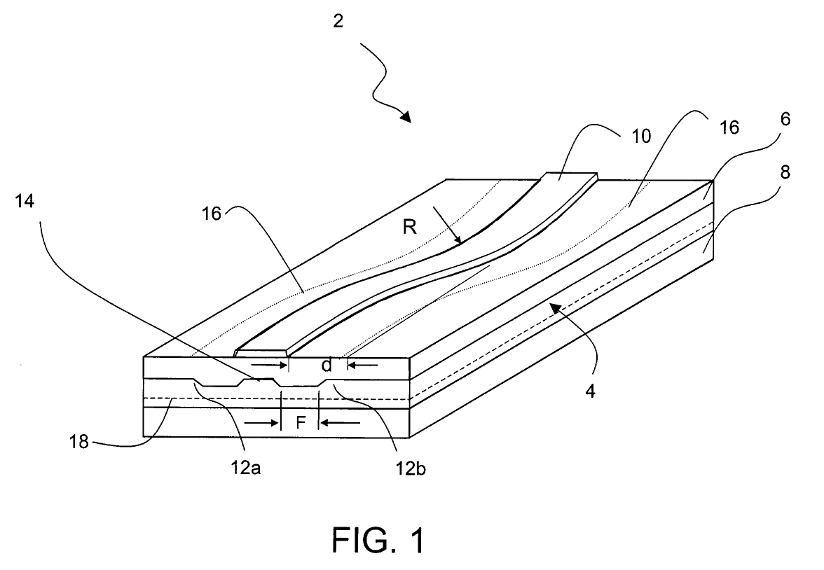

Referring to FIG. 1, a preferred embodiment buried ridge index guide laser is generally indicated at 2. The laser structure 2 has a core 4 between claddings 6, 8 and a top contact 10. The core 4 includes structure to establish a curved and frustrated lateral index guide. The lateral index guide comprises frustrating guides 12a, 12b that flank and frustrate a central index guide 14. The central index guide 14 follows a curved path, and the frustrating guides 12a, 12b are spaced a frustrate distance F away from the central index guide 14. The presence of the frustrating guides 12a, 12b and the curvature in the central index guide 14 establish a spatial filter that induces mode selective loss, discriminating against higher order lateral modes. This prevents the oscillation of higher order modes and thus improves beam quality and eliminates beam steering.

Dashed lines 16 indicate the path of the buried frustrating guides 12a, 12b. The contact 10 is disposed over the central ridge guide 14 and follows its path. Frustrated, as used herein, means that a positive index guide 14 is flanked in close proximity by the additional frustrating positive index guides 12a, 12b on either side, which are maintained away, at a frustrate distance F, from the positive central index guide 14. When the frustrating guides 12a, 12b are in close proximity to the central guide 14, optical energy will be transferred out of the central index guide 14.

The core 4 also includes an embedded a quantum well (“QW”) 18 (indicated with a dashed line) as a gain media. Artisans will appreciate that embodiments of the invention may use other gain media, such as those used in double heterostructure and quantum cascade lasers.

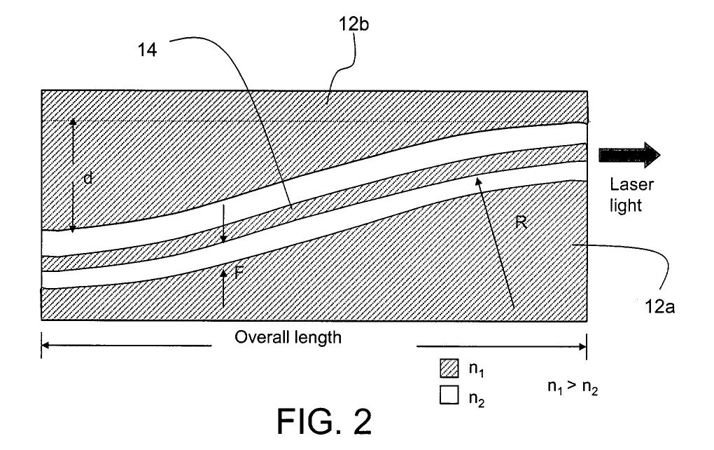

Referring also now to FIG. 2, the preferred FIG. 1 frustrating index guides 12a, 12b are continuous positive index guides that follow the longitudinal path of the central guide 14. Symbols n₁, n₂ (where n₁>n₂) indicate effective refractive index of the core 4 including the central guide 14 and the frustrating index guides 12a, 12b. The central guide 14 includes a radius of curvature R and a displacement d defined by the radius of curvature R. The central guide has a constant width, while the width of the guides 12a and 12b changes to maintain the frustrate distance F from the central guide 14. The amount of optical power leakage from the central guide 14 into the frustrating guides 12a and 12b is determined by the degree to which a mode's optical field overlaps the frustrating guides 12a, 12b. Since high order modes always have a wider spatial extent than the fundamental mode, the field of the high order mode overlaps the frustrating guides more and experiences a larger loss than the fundamental mode. The curvature in the central guide 14 introduces bend loss. Higher order modes experience more bend loss than the fundamental mode as they go around a curve. This disparity in loss can be used to raise the threshold of higher order modes relative to the fundamental mode. With the pair of frustrating and curved index guides 12a, 12b, the stability of the fundamental mode is improved, while optical energy of higher order modes is transferred out of the central guide 14.

Thus, in the FIGS. 1 and 2 embodiment, the radius of curvature R and the frustrate distance F control the amount of loss introduced for higher order modes in the central guide 14. Smaller radii of curvature R increase losses. The smaller the distance F, preferably between 3 μm to 6 μm, the more loss there will be in modes propagating in the central guide 14. As shown, the radius of curvature R preferably reflects an s-bend or a cosine-shaped index guide structure. By way of example only, a preferred embodiment according to FIGS. 1 and 2 has a frustrate distance F of 5 μm, a central ridge guide 14 width W of 2 μm, an index step of 0.0035, a radius of curvature R of 12.5 cm, and a displacement d of 80 μm. The radius of curvature R is preferably in a range between 12-20 cm. In general, the frustrating guides 12a, 12b should be wide enough to appear semi-infinite to the higher order light.

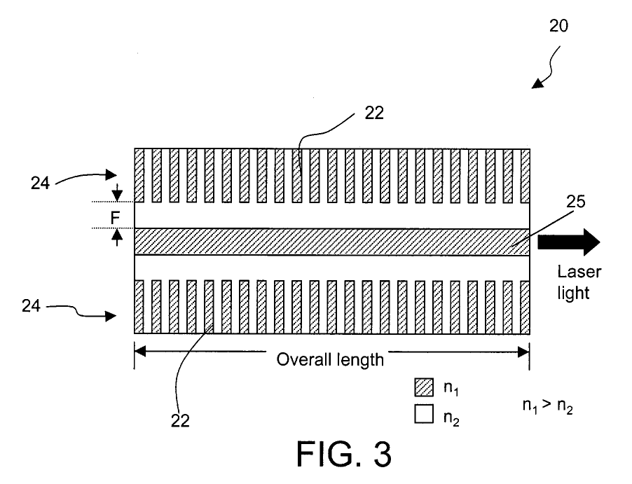

In accordance with another embodiment of the invention, the frustrate losses are introduced by frustrating guides that include laterally disposed and positive index guides that are discontinuous. These positive index guides are referred to as scattering centers. A preferred embodiment 20 of the invention with scattering centers 22 forming two frustrating guides 24 is shown in FIG. 3. Each of the scattering centers 22 is a positive index guide, e.g., a ridge, disposed in the lateral direction. A central guide 25, e.g., a ridge, is disposed longitudinally, emitting single mode laser light. The scattering centers 22, each of which is a guide separated from the next by a space, are located at the frustrate distance F from the central guide 25. As explained above, the frustrate distance F affects the amount of loss in the guide structure. The preferred range of distance F is between 3 μm and 6 μm. For an exemplary layout of a frustrate distance F of 5 μm, the frustrate period is preferably approximately 2 μm with an overall device length of 2 mm.

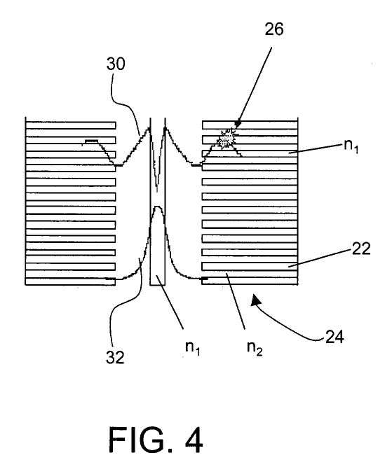

The effect of scattering centers 22 is illustrated in FIG. 4. Scattering (indicated at 26) occurs when the higher mode light is incident on a boundary between regions of differing refractive indices, which are introduced by the scattering centers 22. Scattering occurs at each interruption of the frustrating guides 24 formed by the scattering centers 22. Higher mode light of a dual mode light beam 30 experiences loss due to the scattering centers 22, while a single mode light beam 32 experiences low losses through the central guide 24. If the scattering centers are periodic, as opposed to random, the interruptions should be an odd multiple of half the lasing wavelength with a 50% duty cycle to maximize out-of-plane diffraction and minimize in-plane diffraction (distributed feedback). When the period is equal to the wavelength of the light divided by 2 divided by the modal refractive index, then the scattering will be maximized. As the period decreases below that, then the scattering will be reduced. Alternatively, the scattering centers may be randomized to achieve the same goal of minimizing scattering that can promote distributed feedback.

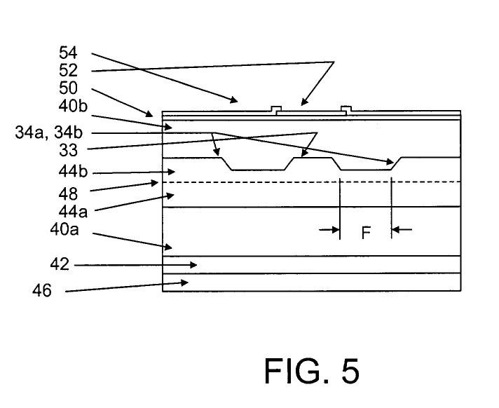

A preferred fabrication process suitable for creating lasers in accordance with the invention will be illustrated with respect to an exemplary device shown in FIG. 5. A first MOCVD growth forms layers up to an index guide, namely an n-Al_{0.2}Ga_{0.8}As cladding layers 40a formed on a n-GaAs buffer layer 42, GaAs barrier layers 44a, 44b, and a quantum well 48, which are grown upon an n-GaAs substrate 46. Exemplary preferred thicknesses include: cladding layers—1000 nm, buffer layer—100 nm, barrier layers (44a 44b)—500 nm and 400 nm, respectively. The Al_{0.2}Ga_{0.8}As material system and the dimensions are not limiting, but just illustrate the preferred example. A quantum well (“QW”) In_{0.26}Ga_{0.74}As 48, preferably having a 7 nm thickness, is formed at the interface of barrier layers 44a and 44b. The buffer layer 42, the cladding layer 40a, the barrier layers 44a, the QW 48, and the barrier layer 44b are all formed in the first of the three MOCVD growths.

A second of three growths is carried out after suitable patterning to define a pattern for the selective area growth of a central ridge guide 33 and the frustrating guides 34a, 34b. For example, regions of the barrier layer 44b may be masked off with SiO₂ such that growth occurs only in windows in the SiO₂ mask. An exemplary thickness for the central ridge guide 33 and the frustrating scattering index guides 34a, 34b is 100 nm. FIG. 5 illustrates the formation of a buried ridge waveguide laser. In the formation of a ridge waveguide laser, patterning is used instead to form the ridge on the top of the structure. A simple core is formed instead of the central ridge guide 33. A self-aligned laser is also formed with a simple core, followed by etching or other material removal of a subsequent cladding to define self aligned index guides in the cladding.

For the third growth, another p-Al_{0.2}Ga_{0.8}As cladding layer 40b, preferably 700 nm, is formed on the index guides 33, 34a, 34b and spaces therebetween. An etch stop 50 including p-Al_{0.6}Ga_{0.4}As is then formed on the cladding layer 40b and a p-GaAs cap layer 52 (i.e., the contact layer) capping the cladding layer 40b. The cladding layer 40b, the etch stop 50 and the contact layer 52 are all doped as p-type layers. The p-GaAs contact layer is etched off everywhere except directly over the central index guide 33 to limit current spreading. A SiO₂ isolation layer 54 is formed on the etch stop 50 on the sides of the contact layer 52. The preferred thickness of the etch stop layer 50 and the contact layer 52 is 100 nm, and the isolation layer 54 is preferably 60 nm. In the formation of a ridge waveguide laser, a contact layer is formed directly upon the ridge.

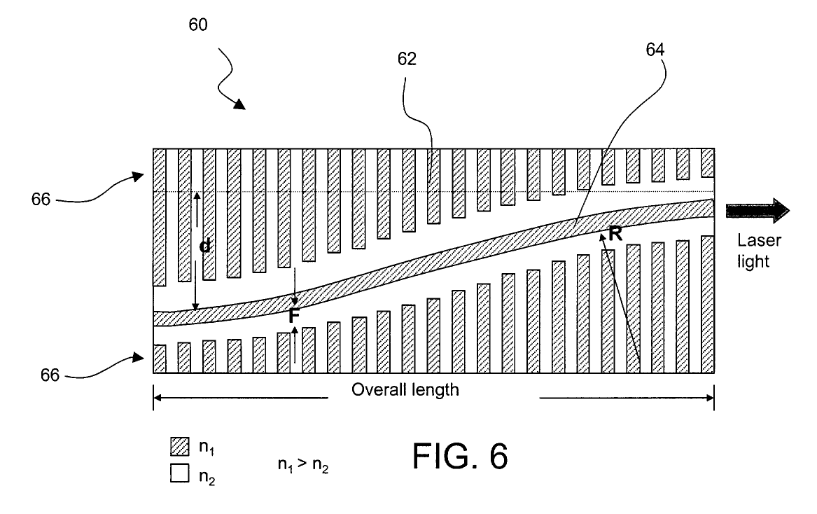

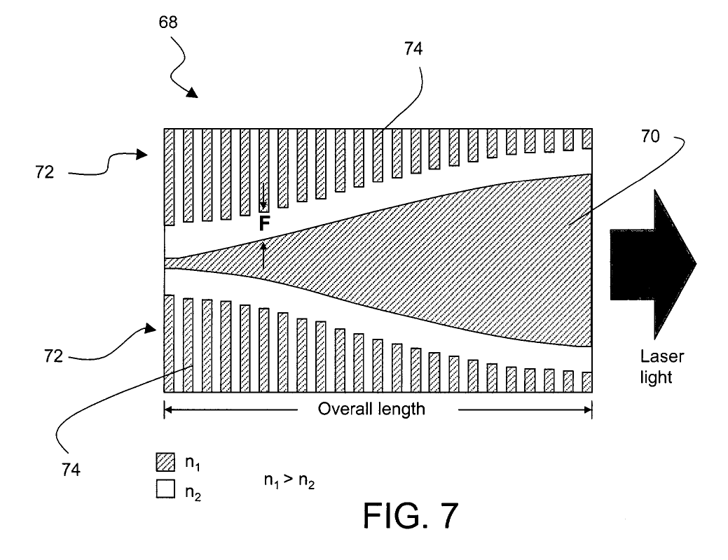

FIG. 6 shows a top sectional view of an index guide structure 60 for an alternate embodiment laser of the invention. Scattering centers 62 are formed at a constant frustrate distance F from a frustrated curved central index guide 64. The scattering centers, as in the previous embodiments, are positive index guides, e.g., ridges. Combined, the scattering centers 62, which have a raised effective refractive index, also act to frustrate the central index guide 64. They may be considered to form two frustrating guides 66. The central index guide 64 also has the bend losses of the FIGS. 1 and 2 embodiment. FIG. 7 illustrates another index guide structure 68 of the invention. A central index guide 70 is a flared index guide that is frustrated by two frustrating guides 72 arranged at a distance F from the central index guide 70. Each of the frustrating guides 72 is formed by a plurality of scattering centers 74.

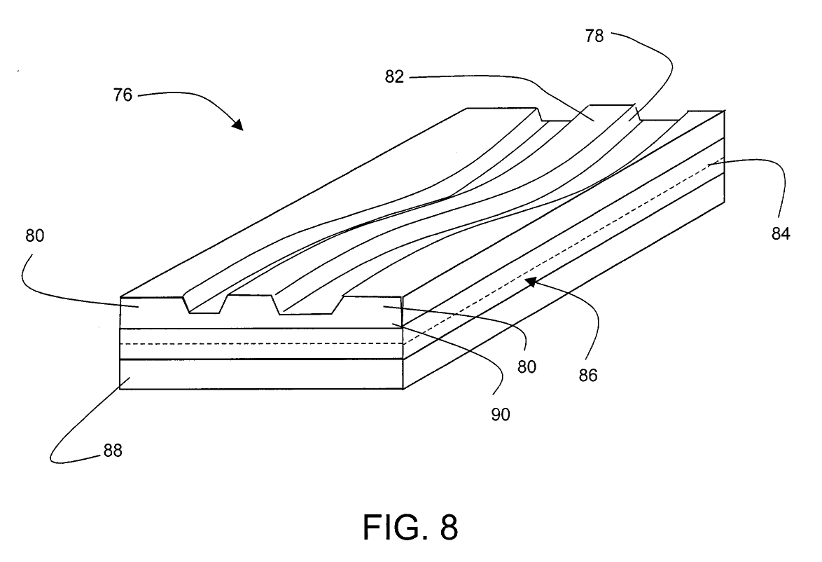

An additional embodiment laser 76 is shown in FIG. 8. The laser 76 is a ridge waveguide laser including an index guide in accordance with the FIGS. 1 and 2 embodiment of the invention. A central curved ridge guide 78 is frustrated by two frustrating guides 80 disposed at a distance F from the central ridge guide 78. A contact 82 is made upon the central ridge 78, and optical gain is through a quantum well 84 formed within a core 86. The core is clad by claddings 88, 90. The design principles of the similar index guides previously discussed with respect to FIGS. 1 and 2 apply equally to the FIG. 8 embodiment. A variation of the FIG. 8 embodiment replaces the frustrating guides with frustrating guides formed from scattering centers as in the index guides, for example, shown in FIGS. 3, 6 and 7.

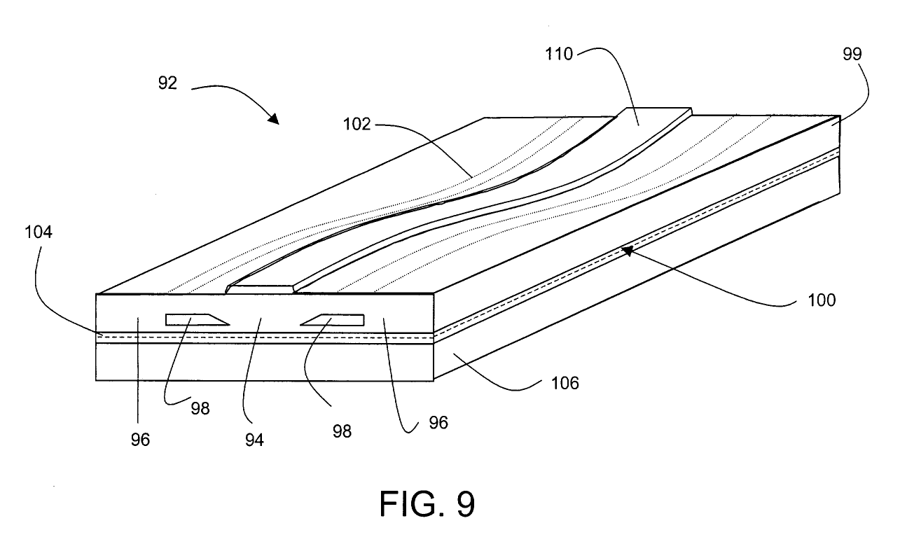

A self-aligned laser embodiment of the invention 92 is shown in FIG. 9 It has the preferred index guide of FIGS. 1, 2 and 8, with a central curved waveguide 94 and two frustrating guides 96. Lower refractive index material structures 98 formed by deposit of material in an etched area of a formed top cladding 99 (and a subsequent overdeposit of cladding material 99) define the self-aligned and curved path of the central and frustrating guides as indicated by dotted lines 102. The central guide 94 is the portion of the cladding 99 between the structures 98 and the frustrating guides are portions of the cladding 99 on the opposite sides of the structures 98. A core 100 includes a gain media formed by a quantum well 104, with the core 100 clad by top and bottom claddings 99, 106. A contact 110 is aligned with the central guide 94. A variation of the FIG. 9 embodiment replaces with frustrating guides 96 with frustrating guides formed from scattering centers.

While specific embodiments of the present invention have been shown and others described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. An index guide structure for a semiconductor laser comprising:
a central guide including a curve to induce bend losses; and
frustrating guides formed a frustrate distance from said central guide and disposed on opposite sides of said central guide.

2. The index guide structure according to claim 1, wherein a width of said central guide is approximately 2 μm and a thickness of said central guide is configured to create a lateral index step of approximately 0.0035 μm.

3. The index guide structure according to claim 1, wherein said frustrating guides each comprise a plurality of scattering centers.

4. The index guide structure according to claim 3, wherein said scattering centers comprise a plurality of laterally disposed guides separated from each other in random periodicity.

5. The index guide structure according to claim 3, wherein said scattering centers comprise a plurality of laterally disposed guides separated from each other in a periodicity that is an odd multiple of half a lasing wavelength to be guided by said index guide.

6. The index guide structure according to claim 1, wherein said frustrating guides each comprise regions that induce scattering losses.

7. The index guide structure according to claim 1, formed as part of a buried ridge laser wherein said central guide comprises a central ridge guide and said frustrating guides comprise part of a core of said buried ridge laser, the laser further comprising:
a gain media within said core;
claddings around said core; and
a contact aligned with said central ridge guide and separated from said core by one of said claddings.

8. The index guide structure according to claim 7, wherein said gain media comprises a quantum well.

9. The index guide structure according to claim 1, formed as part of a ridge waveguide laser wherein said central guide comprises a central ridge guide and said central ridge guide and said frustrating guides comprise part of a ridge waveguide of said ridge waveguide laser, the laser further comprising:
a core;
a gain media within said core;
claddings around said core and separating said ridge waveguide from said core; and
a contact upon said central ridge guide.

10. The index guide structure according to claim 9, wherein said gain media comprises a quantum well.

11. The index guide structure according to claim 1, formed as part of a self-aligned laser wherein said central guide and said frustrating guides comprise part of a top cladding of said self-aligned laser, the laser further comprising:
a core including a gain media;
the core being clad by a bottom cladding and the top cladding; and
a contact aligned with said central guide and separated from said core by said top cladding.

12. The index guide structure according to claim 11, wherein said gain media comprises a quantum well.

13. The index guide structure according to claim 1, wherein said frustrate distance is in the approximate range of 3-6 μm.

14. The laser structure according to claim 1, wherein said curve is substantially cosine shaped.

15. The index guide laser structure according to claim 1, wherein said curve has a radius of curvature in the approximate range of 12-20 cm.

16. The index guide laser structure according to claim 15, wherein said frustrate distance is in the approximate range of 3 μm-6 μm.

17. An index guide structure for a semiconductor laser comprising:
a central guide; and
frustrating guides formed a frustrate distance from said central guide and disposed on opposite sides of said central guide, each of said frustrating guides inducing scattering losses.

18. The index guide structure according to claim 17, wherein a width of said central guide is approximately 2 μm and a thickness of said central guide is configured to create a lateral index step of approximately 0.00351 μm.

19. The index guide structure according to claim 17, wherein said frustrating guides are formed from scattering centers that comprise a plurality of laterally disposed guides separated from each other in random periodicity.

20. The index guide structure according to claim 17, wherein said frustrating guides are formed from scattering centers that comprise a plurality of laterally disposed guides separated from each other in a periodicity that is an odd multiple of half a lasing wavelength to be guided by said index guide.

21. The index guide structure according to claim 17, formed as part of a buried ridge laser wherein said central guide comprises a central ridge guide and said frustrating guides comprise part of a core of said buried ridge laser, the laser further comprising:
a gain media within said core;
claddings around said core; and
a contact aligned with said central ridge guide and separated from said core by one of said claddings.

22. The index guide structure according to claim 21, wherein said gain media comprises a quantum well.

23. The index guide structure according to claim 17, formed as part of a ridge waveguide laser wherein said central guide comprises a central ridge guide and said central ridge guide and said frustrating guides comprise part of a ridge waveguide of said ridge waveguide laser, the laser further comprising:
a core;
a gain media within said core;
claddings around said core and separating said ridge waveguide from said core; and
a contact upon said central ridge guide.

24. The index guide structure according to claim 23, wherein said gain media comprises a quantum well.

25. The index guide structure according to claim 17, formed as part of a self-aligned laser wherein said central guide and said frustrating guides comprise part of a top cladding of said self-aligned laser, the laser further comprising:
a core including a gain media;
the core being clad by a bottom cladding and the top cladding; and
a contact aligned with said central ridge guide and separated from said core by said top cladding.

26. The index guide structure according to claim 25, wherein said gain media comprises a quantum well.

27. The index guide structure according to claim 17, wherein said frustrate distance is in the approximate range of 3-6 μm.

28. The laser structure according to claim 17, wherein said central waveguide includes a curve that is substantially cosine shaped.

29. The index guide laser structure according to claim 28, wherein said curve has a radius of curvature in the approximate range of 12-20 cm.

30. The index guide laser structure according to claim 29, wherein said frustrate distance is in the approximate range of 3 μm-6 μm.

31. The index guide laser structure according to claim 17, wherein said central guide comprises a flared guide.

32. A method for limiting higher order modes in an index guide of a laser structure, the method comprising steps of:
limiting higher order lateral mode oscillation with a combination of two spatial filter elements;
limiting beam steering with said combination of two spatial filter elements.

33. A method for limiting higher order modes in a the index guide of a laser structure, the method comprising steps of:
subjecting higher order modes to bend losses in a central guide of the index guide; and
frustrating the central guide.

34. The method according to claim 33, wherein said step of frustrating comprises utilizing periodic changes in the refractive index outside the central guide to induce scattering loss in the higher order modes.
